(19) United States
(12) Patent Application Publication
(10) Pub. No.: US 2020/0081470 A1
(43) Pub. Date: Mar. 12, 2020

(54) VOLTAGE REGULATOR

(71) Applicant: Nordic Semiconductor ASA, Trondheim (NO)

(72) Inventor: Samuli HALLIKAINEN, Trondheim (NO)

(73) Assignee: Nordic Semiconductor ASA, Trondheim (NO)

(21) Appl. No.: 16/465,124

(22) PCT Filed: Nov. 30, 2017
(86) PCT No.: PCT/GB2017/053612

§ 371 Date: May 29, 2019

(30) Foreign Application Priority Data
Nov. 30, 2016 (GB) 1620335.8

(51) Int. Cl. G05F 1/575; G05F 1/573; H03F 3/45

(52) U.S. Cl. CPC G05F 1/575; H03F 3/45183; G05F 1/573

(57) ABSTRACT

A low-dropout voltage regulator arranged to regulate an output voltage (VDD) comprising: a differential amplifier portion including a first amplifier input connected to a reference voltage (VREF), a second amplifier input, and a differential output which is determined by a difference between the reference voltage and a voltage on the second amplifier input; an output portion arranged to provide a regulator output voltage controlled by the differential output of the differential amplifier portion, wherein the second amplifier input is connected to or derived from the regulator output voltage; a first biasing portion arranged to provide a first bias current to the differential amplifier portion which depends on an external load current; and a second biasing portion comprising a DC-blocking capacitor (C0) connected to the output portion so as to provide a second bias current to the differential amplifier portion which depends on the rate of change of the output voltage.

The present invention relates to voltage regulators, particularly low-dropout voltage regulators.

Modern battery powered system-on-chip (SoC) devices are typically arranged to be operated in different power modes. For example, the SoC may have a first, “normal” mode of operation in which a particular amount of current is used, but may also have a second, “low power” mode of operation to be used when there is no or little activity (e.g. processor tasks) being carried out by the SoC where the low power mode has a lower current consumption associated with it than the normal mode. The difference in current consumption between the normal and low power modes in some SoC devices can be as great as six orders of magnitude. These voltage regulators are arranged to regulate an input voltage down to a lower, regulated voltage. For example, the regulators may be arranged to receive an input voltage or “battery voltage” of 3.7 V from a lithium ion (Li-Ion) battery and produce a stable, regulated output voltage or “system voltage” of 1.8 V.

It is a common goal to minimise current consumption as much as possible in battery powered devices with a view to maintaining as high a battery life as possible. In order to reduce current consumption, an SoC may be provided with two or more voltage regulators that convert the battery voltage to the system voltage, where different voltage regulators are used in each mode of operation as required. By way of non-limiting example only, such an SoC may include an ultra-low power (ULP) low-dropout(LDO) voltage regulator arranged to provide currents less than 1 mA; and a high voltage LDO voltage regulator arranged to provide currents greater than 1 mA.

LDO voltage regulators are linear DC voltage regulators that are capable of operating with very low input-output differential voltages. Such regulators are usually chosen because they have a low minimum operating voltage, high power efficiency and low heat dissipation.

The Applicant has appreciated that in typical LDO voltage regulators high power efficiency is not achieved unless the regulator is operating near to its maximum design load current since the quiescent current it draws is dictated by this maximum load. However the Applicant has further appreciated that in practice in most applications the LDO regulator is only required to deliver at or close to its maximum load current for a very small proportion of the time. The actual efficiency achieved in practice is therefore significantly lower than the theoretical value.

Whilst the issue set out above can be addressed by providing adaptive biasing, the Applicant has also appreciated that such LDO voltage regulators are usually unable to respond adequately to transients (e.g. sudden steps up) in load current. LDO voltage regulators known in the art cannot source sufficient bias current at the required rate in order to respond to the sudden change in load current, especially outside an ultra low power operating range.

When viewed from a first aspect, the present invention provides a low-dropout voltage regulator arranged to regulate an output voltage, said low-dropout voltage regulator comprising:
a differential amplifier portion including a first amplifier input connected to a reference voltage, a second amplifier input, and a differential output which is determined by a difference between said reference voltage and a voltage on the second amplifier input;
an output portion arranged to provide a regulator output voltage which is controlled by the differential output of the differential amplifier portion, wherein said second amplifier input is connected to or derived from said regulator output voltage;
a first biasing portion arranged to measure an external load current and to provide a first bias current to the differential amplifier portion which depends on said load current; and
a second biasing portion comprising a DC-blocking capacitor connected to said output portion such that the second biasing circuit portion measures a rate of change of said output voltage and provides a second bias current to the differential amplifier portion which depends on said rate of change.

Thus it will be appreciated by those skilled in the art that the present invention provides a low-dropout (LDO) voltage regulator that can adapt the level of bias current that is provided to the differential amplifier based upon the current being drawn by the load. This means that when providing small load currents, the LDO regulator does not require a large quiescent current, significantly reducing the power consumption of the circuit at low loads, while still allowing for the bias current to be “ramped up” in order to maintain stability in the event that a large load current is needed. By adaptively biasing the LDO regulator in this manner, the circuit may also achieve an improved bandwidth and transient response when compared to conventional LDO regulators.

The first biasing portion allows a LDO regulator in accordance with embodiments of the present invention to scale the first bias current in order to ensure the dominant pole tracks the dominant pole in the input. The Applicant has appreciated however that the first biasing portion alone may not always be capable of responding to transients (i.e. sudden, sharp changes) in the load current. The second biasing portion provides the LDO regulator with the capability to respond to transients in the load current by “boosting” the amount of bias current provided to the differential amplifier in response to a high rate of change of the load current.

Differential amplifier portions in accordance with the present invention are therefore provided with two sources of variable bias current. The first arises from the first biasing portion and is dependent on the magnitude of the external load current while the second arises from the second biasing portion and is dependent on the rate of change of the external load current. The advantage of a DC-blocking capacitor connected to the output portion is that it provides feedforward control over the bias current such that the bias current can be increased rapidly in response to a step in the load current.

It will be appreciated that the differential amplifier portion will typically be provided with an additional, static source of bias current that remains constant regardless of the external load current.

The Applicant has appreciated that the voltage regulator of the present invention may advantageously reach its maximum output current more quickly than a conventional voltage regulator would. In a preferred set of embodiments, the voltage regulator further comprises a current comparator arranged to compare a total bias current provided to the differential amplifier portion to a threshold and to generate an overcurrent flag if the bias current exceeds said threshold. It should be understood that the total bias current is a sum of the first bias current, the second bias current, and any additional static bias current as described above.

This overcurrent flag may then be used to indicate (e.g. to a controller) that the load current exceeds the maximum output current of the LDO voltage regulator and that a further, higher power voltage regulator should be enabled in order to supply the reference voltage. Thus, in embodiments of the invention wherein the LDO voltage regulator forms part of a larger circuit having a further voltage regulator with a higher maximum output current than that of the LDO voltage regulator, the overcurrent flag generated by such a current comparator may be used to selectively enable the further voltage regulator.

The Applicant has appreciated that as the current comparator is “inside the loop” of the LDO voltage regulator, it may not be able to detect that the load current is too large for the LDO voltage regulator as quickly as may be desirable. This is because the current comparator is coupled only to the output current and is therefore independent of the magnitude and slew rate of any transients in the load. However, when applied to the voltage regulator of the present invention, by increasing the bias current provided to the differential amplifier in response to the rate of change of the load current, the current comparator will generate the overcurrent flag more quickly than it would with a conventional LDO voltage regulator, thus reducing the amount of time required before the higher power voltage regulator is enabled.

As with any circuit, the differential amplifier of an LDO regulator has an associated transfer function which describes the frequency response of the circuit. The transfer function typically has a pole located at a particular frequency known as a corner frequency. Once the frequency of the lowest frequency or “dominant” pole has been reached, the gain of the circuit begins to decrease at a rate of 20 dB/decade (i.e. for every ten-fold increase in frequency, the gain drops by 20 dB). Any subsequent poles will then increase this rate by a further 20 dB/decade. Each pole will also introduce a 90 degree phase shift. Thus with two poles, the output is then in anti-phase (i.e. 180 degrees out of phase) with the input, which can cause the circuit to be unstable. Thus in order for a circuit to be stable, the gain should ideally drop to unity at a frequency lower than that of the second pole (i.e. the first “non-dominant” pole).

Since any output capacitance and resistance form a first order low-pass filter, the corner frequency f_{c} which corresponds to the dominant pole of the LDO regulator can be calculated as per Equation 1.

$${f}_{c} = \frac{1}{2 π RC} \qquad Equation 1$$

In this equation, C is the capacitance of the output capacitor and R is the parallel combination of the resistance of the load, R_{load}, and the amplifier's output resistance, Rₒᵤₜ, as per Equation 2 below.

$$R = {R}_{out} \frac{{R}_{load}}{( {R}_{out} + {R}_{load} )} \qquad Equation 2$$

In such arrangements when the load current is large, the resistance of the load is small, which shifts the frequency of the dominant pole higher. The output resistance of the amplifier is also small when the load current is large and thus does not prevent the dominant pole being shifted to higher frequencies with increasing load current.

This shifting of the dominant pole to higher frequencies may cause stability issues because it does not shift the non-dominant poles, meaning that the second pole could exist at a frequency lower than that at which the gain drops to unity. This is counteracted by having a relatively high bias current for the differential amplifier. However in conventional arrangements this bias current is fixed, meaning the regulator wastes power at low loads providing a high bias when it is not required. In accordance with the invention however the first bias current is only increased when necessary, i.e. at higher load currents and/or when there is a rapid change in load current, making embodiments of the invention more power efficient across a wide range of load currents whilst maintaining stability.

While it will be appreciated by those skilled in the art that there are many differential amplifier topologies which could be utilised to implement the present invention, in at least some preferred embodiments the differential amplifier portion comprises a long tailed pair comprising:
first and second differential pair transistors having their respective source terminals connected together and to said first and second biasing portions so as to be driven by said first and second biasing currents respectively; and
a tail transistor arranged such that its drain terminal is connected to the respective source terminals of said first and second differential pair transistors;
wherein the first amplifier input comprises the gate terminal of the first differential pair transistor, the second amplifier input comprises the gate terminal of the second differential pair transistor, and the differential output comprises the drain terminal of the first differential pair transistor.

In some such embodiments, the long tailed pair further comprises a current mirror comprising first and second mirror transistors arranged such that:
the drain terminal of the first mirror transistor is connected to the drain terminal of the first differential pair transistor;
the drain terminal of the second mirror transistor is connected to the gate terminal of said second mirror transistor and to the drain terminal of the second differential pair transistor; and
the gate terminals of the first and second mirror transistors are connected to each other.

In some embodiments, the output portion comprises an output transistor arranged such that: its source terminal is connected to the input voltage; its drain terminal is connected to the output voltage; and its gate terminal is connected to the differential output of the differential amplifier portion. It will be appreciated by those skilled in the art that such an arrangement allows the output transistor to vary the regulator output voltage depending on the voltage applied to its gate terminal by the differential amplifier portion. In embodiments wherein the differential amplifier comprises a long tailed pair, the gate terminal of the output transistor is connected to the drain terminal of the first differential pair transistor.

While it will be appreciated that there are a number of circuit topologies suitable for implementing the first biasing portion to provide the adaptive bias current in response to the magnitude of the load current, in some preferred embodiments the first biasing portion comprises:
an adaptive bias tail transistor, wherein the drain terminal of said adaptive tail transistor is connected to the differential amplifier portion;
a driver transistor, wherein the source terminal of the driver transistor is connected to the input voltage and the gate terminal of the driver transistor is connected to the differential output of the differential output portion; and
an adaptive bias low pass filter connected between the drain terminal of said driver transistor and the gate terminal of said adaptive bias tail transistor.

In some such embodiments, said first biasing portion further comprises first and second diode-connected transistors arranged in series, such that:
the gate and drain terminals of the first diode-connected transistor are connected to the drain terminal of the driver transistor;
the gate and drain terminals of the second diode-connected transistor are connected to the source terminal of the first diode-connected transistor.

In some further such embodiments, the adaptive bias low pass filter comprises first and second adaptive bias filter transistors, arranged such that:
the gate terminal of the first adaptive bias filter transistor is connected to the drain terminal of the driver transistor;
the gate terminal of the second adaptive bias filter transistor is connected to the source terminal of the first adaptive bias filter transistor and to the gate terminal of the adaptive bias tail transistor; and
the drain and source terminals of the second adaptive bias filter transistor are connected to ground. Thus it will be appreciated that in accordance with such embodiments, the first adaptive bias filter transistor acts as a resistor and the second adaptive bias filter transistor acts as a capacitor so as to provide a low pass “RC” filter. In embodiments wherein the first biasing portion comprises first and second diode-connected transistors, the drain terminal of the second adaptive bias filter transistor may be connected to the gate and drain terminals of the second diode-connected transistor.

In some embodiments, the first biasing portion comprises a low pass filter. Such embodiments introduce an additional non-dominant pole that responds to the load current. This may help to ensure that when higher load currents are provided and the dominant pole is shifted to a higher frequency, the first non-dominant pole is also shifted to a higher frequency such that unity gain is reached before the second pole.

It will also be appreciated that there are a number of circuit topologies suitable for implementing the second biasing portion to provide a boosted bias current in response to a high rate of change in the load current. In some preferred embodiments the second biasing portion comprises a boost input transistor and a boost current mirror comprising first and second boost mirror transistors, wherein:
the gate terminal of the boost input transistor is connected to the regulator output voltage via the DC-blocking capacitor;
the drain terminal of the boost input transistor is connected to the gate terminals of the first and second boost mirror transistors and to the drain terminal of the first boost mirror transistor; and
the drain terminal of the second boost mirror transistor is connected to the differential amplifier portion.

Thus it will be appreciated by those skilled in the art that, in accordance with such embodiments, the DC-blocking capacitor allows high frequency components associated with a sudden drop in the regulator output voltage to pass which causes the boost input transistor to be enabled and rapidly source additional current to the differential amplifier portion via the boost current mirror. When the regulator output voltage rises back to its desired value, the boost input transistor will become disabled once more, returning the differential amplifier portion to its regular current consumption.

In some such embodiments, the second biasing portion further comprises a reference current mirror, a reference current source and a low pass filter, wherein the reference current mirror comprises first and second reference current mirror transistors, wherein:
the respective gate terminals of the first and second reference current mirror transistors are connected to each other, to the drain terminal of the first reference current mirror transistor and to the reference current source; and
the boost low pass filter is connected between the drain terminal of the second reference current mirror transistor and the gate terminal of the boost input transistor.

While the boost low pass filter may be constructed in any manner known in the art per se, in some embodiments the low pass filter comprises first, second, and third boost filter transistors, wherein the first and second boost filter transistors are arranged in series, each in a diode-connected configuration, and the third boost filter transistor is arranged such that: its drain terminal is connected to the gate terminal of the first boost filter transistor; its gate terminal is connected to the gate terminal of the second boost filter transistor; and its source terminal is connected to the gate terminal of the boost input transistor.

It will be appreciated that in order to provide the second bias current, the second biasing portion must be connected to a voltage source. In preferred embodiments, the source terminal of the first boost mirror transistor is connected to the input voltage. Similarly, in some potentially overlapping embodiments, the source terminal of the boost input transistor is connected to the input voltage.

Certain embodiments of the invention will now be described, by way of example only, with reference to the accompanying drawings in which:

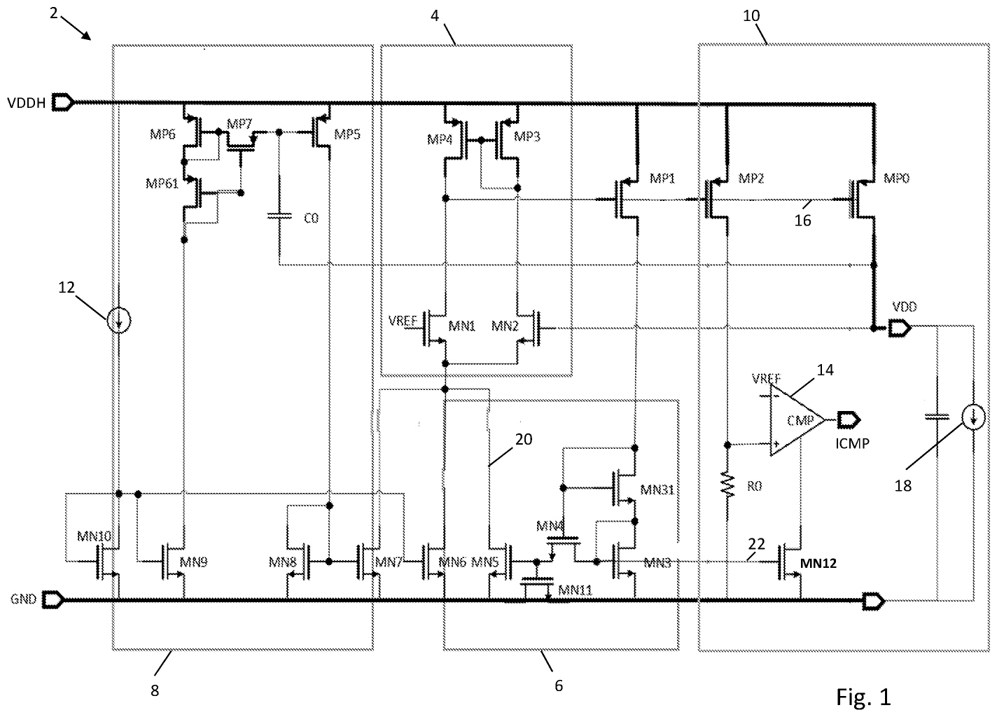

FIG. 1 shows a circuit diagram of a low-dropout voltage regulator in accordance with an embodiment of the present invention; and

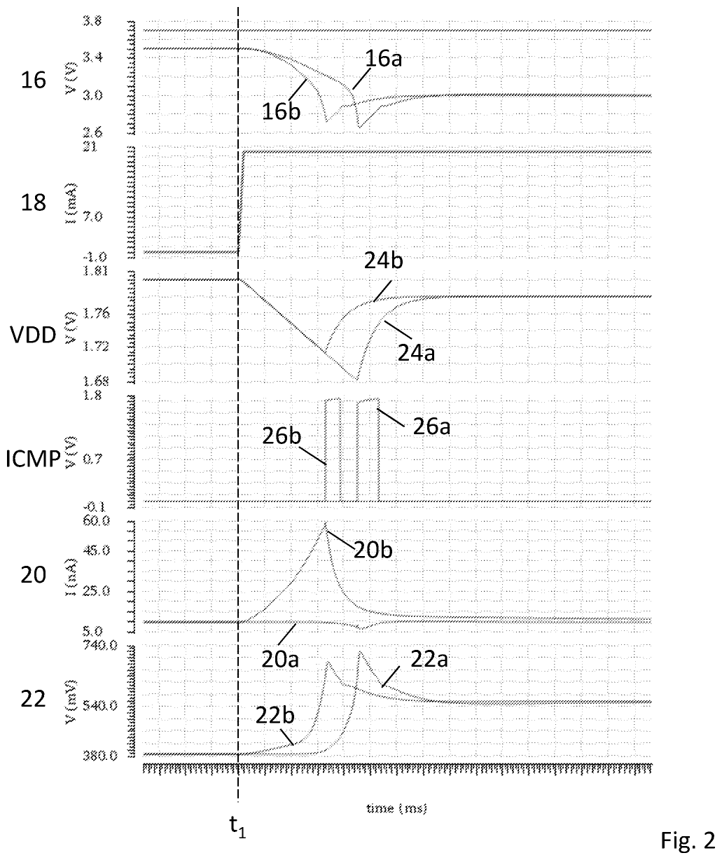

FIG. 2 shows a simulated graph illustrating the response of the circuit shown FIG. 1 to a step in the load current.

FIG. 1 shows a circuit diagram of a low drop-out voltage regulator 2 in accordance with an embodiment of the present invention. While the low drop-out voltage regulator (LDO) 2 would typically be implemented as a single integrated circuit, the LDO 2 is here divided into several separate circuit portions for illustrative purposes only. The LDO 2 comprises: a differential amplifier portion for; a first biasing portion 6; a second biasing portion 8; and an output portion 10. Each of these logical circuit portions will be described in turn below.

The LDO 2 is arranged to regulate an input voltage VDDH to provide an output voltage VDD, wherein the objective is to drive the output voltage VDD to a reference voltage VREF. The differential amplifier portion 4 is arranged as a long-tailed pair and compares the value of the output voltage VDD to the reference voltage VREF and produces an output signal that is proportional to the difference therebetween. The long-tailed pair is constructed from two n-channel metal-oxide-semiconductor field-effect-transistors (nMOSFETS), MN1 and MN2 arranged such that the gate terminal of MN1 is connected to the reference voltage VREF and the gate terminal of MN2 is connected to the output voltage VDD. The respective source terminals of MN1 and MN2 are connected together and are further connected to the drain terminal of an additional tail transistor MN6, the source terminal of which is connected to ground GND. The gate terminal of MN6 is connected to the drain and gate terminals of a reference current transistor MN10 which has its source terminal connected to ground GND. The gate and drain terminals of MN10 are also connected to a current source 12 which is in turn connected to the input voltage VDDH. This reference transistor MN10 provide a bias voltage to the tail transistor MN6 such that the differential amplifier portion 4 is provided with a constant bias current, i.e. MN10 and MN6 form a current mirror such that the differential amplifier portion 4 is provided with the reference current produced by the current source 12.

The differential amplifier portion 4 further comprises another current mirror constructed from two p-channel MOSFETS (pMOSFETS) MP3 and MP4. The source terminals of MP3 and MP4 are both connected to the input voltage VDDH and their respective gate terminals are connected together and to the drain terminal of MP3. The drain terminal of MP3 is connected to the drain terminal of MN2 while the drain terminal of MP4 is connected to the drain terminal of MN1. The drain terminal of MP4 is further connected to the gate terminal of an output transistor MP0. The drain terminal of MP4 is also connected to the gate terminals of two replica transistors MP1 and MP2, which will be described in further detail later.

Any difference between the output voltage VDD and the reference voltage VREF will result in a non-zero voltage being applied to the gate of the output transistor MP0. As the output transistor MP0 has its source terminal connected to the input voltage VDDH and its drain terminal connected to the output voltage VDD, the voltage applied to the gate terminal of MP0 will directly influence the output voltage VDD.

The first or “adaptive” biasing portion 6 comprises an additional tail transistor MN5 arranged such that its drain terminal is connected to the source terminals of MN1 and MN2 and its source terminal is connected to ground GND. The gate terminal of MN5 is connected to the drain terminal of the first replica transistor MP1 via a low pass filter arrangement. The low pass filter arrangement is constructed from a first filter transistor MN11 having its drain and source terminals connected to ground GND and its gate terminal connected to the gate terminal of MN5 and to the source terminal of a second filter transistor MN4. The gate terminal of MN4 is connected to the drain terminal of the first replica transistor MP1 which is then connected to ground GND via two diode-connected transistors MN3 and MN31. It will be appreciated by those skilled in the art that the term “diode-connected” is understood to mean a transistor having its gate and drain terminals connected together. The gate and drain terminals of MN3 are further connected to the drain terminal of MN4.

As the gate terminal of the first replica transistor MP1 is connected to the output of the differential amplifier portion 4, the difference between the output voltage VDD and the reference voltage VREF will cause a current to flow through the first replica transistor MP1. This current is then filtered by the low pass filter arrangement and causes a voltage to be applied to the gate terminal of the tail transistor MN5. This causes the tail transistor MN5 to provide an additional, adaptive bias current to the differential amplifier portion 4, wherein this bias current is dependent on the load current. That is to say that high load current will cause the output voltage VDD to drop below the reference voltage VREF which in turn enables the replica transistor MP1 and this has the consequence of increasing the adaptive bias current provided to the differential amplifier portion 4 such that it can increase the output voltage VDD and drive it back to the desired value of the reference voltage VREF.

The second (or “boost”) biasing portion 8 comprises a boost input transistor MP5 which has its source terminal connected to the input voltage VDDH and its gate terminal connected to the output voltage VDD via a capacitor C0. The gate terminal of MP5 is further connected to the drain terminal of a boost mirror transistor MN9 via a low pass filter arrangement. This boost mirror transistor MP9, which has its source terminal connected to ground and its gate terminal connected to the drain and gate terminals of the reference transistor MN10, provides a small, constant bias voltage to the boost input transistor MP5. The drain terminal of MP5 is connected to a boost current mirror arrangement comprising a diode connected transistor MN8 and a boost tail transistor MP7. The gate terminals of MN7 and MN8 are both connected to the drain terminal of MN8 and to the drain terminal of MP5. The source terminals of MN7 and MN8 are connected to ground GND. The drain terminal of the boost tail transistor MN7 is connected to the source terminals of MN1 and MN2 within the differential amplifier portion 4.

If the output voltage VDD suddenly drops, e.g. as a result of the output current experiencing a sudden increase—particularly if the increase results in the output current exceeding the rated maximum output current of the LDO 2, the capacitor C0 will cause the boost input transistor MP5 to begin conducting and drive current through the diode connected transistor MN8. As the current through diode connected transistor MN8 is mirrored to the boost tail transistor MN7, this drives additional bias current to the differential amplifier portion 4 in response to a rapidly varying output voltage VDD.

The output circuit portion 10 further comprises a comparator 14 arranged such that its positive input is connected to the drain terminal of the second replica transistor MP2 and to a fixed resister R0 which is connected to ground GND. The source terminal of the second replica transistor MP2 is connected to the input voltage VDDH while its gate terminal is connected to the drain terminal of MP4 within the differential amplifier portion 4 as described previously. The other, negative input to the comparator 14 is connected to the reference voltage VREF. This current comparator 14 is arranged to provide at its output a measure of over-current ICMP. That is to say, that the comparator 14 measures the replica current from the second replica transistor MP2 that is driven to ground GND via the fixed resister R0. The current comparator 14 also makes use of adaptive biasing via a comparator biasing transistor MN12. This allows the comparator 14 to require very little quiescent current when not needed. The ICMP signal provided by the comparator 14 may be used to monitor whether or not the regulator is able to provide high current as shown in FIG. 2.

FIG. 2 shows a simulated graph illustrating the response of the circuit 2 shown in FIG. 1 to a step in the load current 18. In this particular example the step in the load current 18 is from an initial value of 1 μA to 20 mA, at an initial time T1. FIG. 2 illustrates the difference in performance achieved by having the second biasing portion 8 present within the LDO circuit 2. As such for comparative purposes FIG. 2 shows two traces for each signal where relevant, wherein traces labelled with a reference numeral appended with “a” indicate that the second biasing portion 8 is disabled whereas traces labelled with a reference numeral appended with “b” indicate that the second biasing portion 8 is enabled. For the purpose of the simulation, this is achieved by disabling or enabling the capacitor C0 respectively, effectively disconnecting or connecting the second biasing portion 8.

At time t₁ the load current 18 experiences a pulse which causes the output voltage VDD to begin dropping as shown by traces 24a and 24b. This sudden change in the output voltage VDD causes the current through the capacitor C0 to rapidly increase. This in turn causes the current 20 provided by the boost tail transistor MN7 to rapidly increase as shown by the trace 20b. By way of contrast, there is no such equivalent current provided when the capacitor C0 is disabled as shown by trace 20a. This causes the voltage 16 applied to the gate of the output transistor MP0 to rise more quickly when the second biasing portion 8 is enabled (shown by trace 16b) when compared to the case when the second biasing portion 8 is disabled (shown by trace 16a).

The voltage 22 applied to the gate terminal of the comparator biasing transistor MN12 also increases earlier in the case where the second biasing portion 8 is enabled as shown by the trace 22b when compared to the case wherein the second biasing portion 8 is disabled as shown by the trace 22a. This causes the output ICMP of the comparator 14 to produce a pulse indicative of over-current earlier when the second biasing portion 8 is enabled as shown by the trace 26b when compared to the case wherein the second biasing portion 8 is disabled as shown by the trace 26a.

Thus it will be appreciated by those skilled in the art that the present invention provided a low drop-out voltage regulator capable of responding to transients in the load current more rapidly when compared to conventional voltage regulators. It will be appreciated by those skilled in the art that the embodiments described above are merely exemplary and are not limiting on the scope of the invention.

1. A low-dropout voltage regulator arranged to regulate an output voltage, said low-dropout voltage regulator comprising:
a differential amplifier portion including a first amplifier input connected to a reference voltage, a second amplifier input, and a differential output which is determined by a difference between said reference voltage and a voltage on the second amplifier input;
an output portion arranged to provide a regulator output voltage which is controlled by the differential output of the differential amplifier portion, wherein said second amplifier input is connected to or derived from said regulator output voltage;
a first biasing portion arranged to measure an external load current and to provide a first bias current to the differential amplifier portion which depends on said load current; and
a second biasing portion comprising a DC-blocking capacitor connected to said output portion such that the second biasing circuit portion measures a rate of change of said output voltage and provides a second bias current to the differential amplifier portion which depends on said rate of change.

2. The low-dropout voltage regulator as claimed in claim 1, wherein the differential amplifier portion is provided with an additional, static source of bias current that remains constant regardless of the external load current.

3. The low-dropout voltage regulator as claimed in claim 1, further comprising a current comparator arranged to compare a total bias current provided to the differential amplifier portion to a threshold and to generate an overcurrent flag if the total bias current exceeds said threshold.

4. The low-dropout voltage regulator as claimed in claim 3, wherein the overcurrent flag generated is used to selectively enable the further voltage regulator.

5. The low-dropout voltage regulator as claimed in claim 1, wherein the differential amplifier portion comprises a long tailed pair comprising:
first and second differential pair transistors having their respective source terminals connected together and to said first and second biasing portions so as to be driven by said first and second biasing currents respectively; and
a tail transistor arranged such that its drain terminal is connected to the respective source terminals of said first and second differential pair transistors;
wherein the first amplifier input comprises the gate terminal of the first differential pair transistor, the second amplifier input comprises the gate terminal of the second differential pair transistor, and the differential output comprises the drain terminal of the first differential pair transistor.

6. The low-dropout voltage regulator as claimed in claim 5, wherein the long tailed pair further comprises a current mirror comprising first and second mirror transistors arranged such that:
the drain terminal of the first mirror transistor is connected to the drain terminal of the first differential pair transistor;
the drain terminal of the second mirror transistor is connected to the gate terminal of said second mirror transistor and to the drain terminal of the second differential pair transistor; and
the gate terminals of the first and second mirror transistors are connected to each other.

7. The low-dropout voltage regulator as claimed in claim 1, wherein the output portion comprises an output transistor arranged such that: its source terminal is connected to the input voltage; its drain terminal is connected to the output voltage; and its gate terminal is connected to the differential output of the differential amplifier portion.

8. The low-dropout voltage regulator as claimed in claim 1, wherein the first biasing portion comprises:
an adaptive bias tail transistor, wherein the drain terminal of said adaptive tail transistor is connected to the differential amplifier portion;
a driver transistor, wherein the source terminal of the driver transistor is connected to the input voltage and the gate terminal of the driver transistor is connected to the differential output of the differential output portion; and
an adaptive bias low pass filter connected between the drain terminal of said driver transistor and the gate terminal of said adaptive bias tail transistor.

9. The low-dropout voltage regulator as claimed in claim 8, wherein the first biasing portion further comprises first and second diode-connected transistors arranged in series, such that:
the gate and drain terminals of the first diode-connected transistor are connected to the drain terminal of the driver transistor;
the gate and drain terminals of the second diode-connected transistor are connected to the source terminal of the first diode-connected transistor.

10. The low-dropout voltage regulator as claimed in claim 8, wherein the adaptive bias low pass filter comprises first and second adaptive bias filter transistors, arranged such that:
the gate terminal of the first adaptive bias filter transistor is connected to the drain terminal of the driver transistor;
the gate terminal of the second adaptive bias filter transistor is connected to the source terminal of the first adaptive bias filter transistor and to the gate terminal of the adaptive bias tail transistor; and
the drain and source terminals of the second adaptive bias filter transistor are connected to ground.

11. The low-dropout voltage regulator as claimed in claim 1, wherein the first biasing portion comprises a low pass filter.

12. The low-dropout voltage regulator as claimed in claim 1, wherein the second biasing portion comprises a boost input transistor and a boost current mirror comprising first and second boost mirror transistors, wherein:
the gate terminal of the boost input transistor is connected to the regulator output voltage via the DC-blocking capacitor;
the drain terminal of the boost input transistor is connected to the gate terminals of the first and second boost mirror transistors and to the drain terminal of the first boost mirror transistor; and
the drain terminal of the second boost mirror transistor is connected to the differential amplifier portion.

13. The low-dropout voltage regulator as claimed in claim 12, wherein the second biasing portion further comprises a reference current mirror, a reference current source and a low pass filter, wherein the reference current mirror comprises first and second reference current mirror transistors, wherein:
the respective gate terminals of the first and second reference current mirror transistors are connected to each other, to the drain terminal of the first reference current mirror transistor and to the reference current source; and
the boost low pass filter is connected between the drain terminal of the second reference current mirror transistor and the gate terminal of the boost input transistor.

14. The low-dropout voltage regulator as claimed in claim 13, wherein the low pass filter comprises first, second, and third boost filter transistors, wherein the first and second boost filter transistors are arranged in series, each in a diode-connected configuration, and the third boost filter transistor is arranged such that: its drain terminal is connected to the gate terminal of the first boost filter transistor; its gate terminal is connected to the gate terminal of the second boost filter transistor; and its source terminal is connected to the gate terminal of the boost input transistor.

15. The low-dropout voltage regulator as claimed in claim 12, wherein the source terminal of the first boost mirror transistor is connected to the input voltage.

16. The low-dropout voltage regulator as claimed in claim 12, wherein the source terminal of the boost input transistor is connected to the input voltage.
